(19) United States
(12) Patent Application Publication
(10) Pub. No.: US 2024/0431145 A1
(43) Pub. Date: Dec. 26, 2024

(54) DISPLAY DEVICE AND METHOD FOR FABRICATION THEREOF

(71) Applicant: Samsung Display Co., LTD., Yongin-si (KR)

(72) Inventors: Dong Min LEE, Yongin-si (KR); Jong Hee PARK, Yongin-si (KR); Su Kyoung YANG, Yongin-si (KR); Joon Yong PARK, Yongin-si (KR); Hyun Eok SHIN, Yongin-si (KR)

(21) Appl. No.: 18/417,960

(22) Filed: Jan. 19, 2024

(30) Foreign Application Priority Data
Jun. 26, 2023 (KR) 10-2023-0081614

(51) Int. Cl. H10K 59/122; H10K 59/12

(52) U.S. Cl. CPC H10K 59/122; H10K 59/1201

(57) ABSTRACT

A display device includes: a first pixel electrode disposed on a substrate, a sacrificial pattern disposed on an edge of the first pixel electrode, a pixel defining film including a body portion disposed on the substrate and a protrusion portion disposed on the sacrificial pattern and exposing the first pixel electrode, a first light emitting layer disposed on the first pixel electrode, a first common electrode disposed on the first light emitting layer, a first bank layer disposed on the pixel defining film, and a second bank layer disposed on the first bank layer and having a side surface protruding more than a side surface of the first bank layer. A first side surface of the sacrificial pattern is aligned with a side surface of the protrusion portion of the pixel defining film or protrudes more than the side surface of the protrusion portion of the pixel defining film.

This application claims priority to Korean Patent Application No. 10-2023-0081614, filed on Jun. 26, 2023, and all the benefits accruing therefrom under 35 U.S.C. § 119, the content of which in its entirety is herein incorporated by reference.

### BACKGROUND

### 1. Technical Field

The present disclosure relates to a display device and a method for fabrication thereof.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions. The display devices may be flat panel display devices such as liquid crystal display devices, field emission display devices, or organic light emitting display devices. Among such flat panel display devices, a light emitting display device may display an image without a backlight unit providing light to a display panel because each of pixels of the display panel includes light emitting elements that may emit light by themselves.

The display devices have been applied to glasses-type devices for providing virtual reality and augmented reality. The display device is implemented in a very small size of 2 inches or less in order to be applied to the glasses-type device, but should have a high pixel integration degree in order to be implemented with high resolution. For example, the display device may have a high pixel integration degree of 1,000 pixels per inch (PPI) or more.

When the display device is implemented in the very small size but has the high pixel integration degree as described above, areas of emission areas in which light emitting elements are disposed are reduced, and thus, it is difficult to implement light emitting elements separated from each other for each emission area through a mask process.

### SUMMARY

Aspects of the present disclosure provide a display device capable of forming light emitting elements separated from each other for each emission area without a mask process.

Aspects of the present disclosure also provide a display device of which reliability of a display panel is improved by preventing the occurrence of void spaces at boundaries between pixel electrodes, sacrificial patterns, and a pixel defining film.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an embodiment of the disclosure, a display device include a first pixel electrode disposed on a substrate, a first sacrificial pattern disposed on an edge of the first pixel electrode, a pixel defining film including a body portion disposed on the substrate and a protrusion portion disposed on the first sacrificial pattern and exposing the first pixel electrode, a first light emitting layer disposed on the first pixel electrode, a first common electrode disposed on the first light emitting layer, a first bank layer disposed on the pixel defining film, and a second bank layer disposed on the first bank layer and having a side surface protruding more than a side surface of the first bank layer, where a first side surface of the first sacrificial pattern is aligned with a side surface of the protrusion portion of the pixel defining film or protrudes more than the side surface of the protrusion portion of the pixel defining film.

The first sacrificial pattern may include molybdenum (Mo).

The first sacrificial pattern may have a second side surface opposite to the first side surface, and the pixel defining film may be disposed on the second side surface of the first sacrificial pattern.

The side surface of the protrusion portion of the pixel defining film may protrude more than the side surface of the second bank layer.

A thickness of the first sacrificial pattern may be 50 angstroms (Å) to 600 Å.

An upper surface of the first sacrificial pattern may be in contact with the protrusion portion of the pixel defining film, and a lower surface of the first sacrificial pattern may be in contact with the first pixel electrode.

The first pixel electrode may be a multilayer film made of indium tin oxide (ITO)/silver (Ag)/ITO, aluminum (Al)/titanium nitride (TiN), or Al/Ti.

An entire lower surface of the protrusion portion of the pixel defining film may be in contact with the first sacrificial pattern.

The first common electrode and the first light emitting layer may be in contact with the first bank layer, and a contact area between the first common electrode and the first bank layer may be greater than a contact area between the first light emitting layer and the first bank layer.

The first bank layer may include aluminum (Al), and the second bank layer may include titanium (Ti).

The display device may further include a first inorganic layer disposed on an upper surface of the first common electrode, the side surface of the first bank layer, and a lower surface and an upper surface of the second bank layer.

The display device may further include a second pixel electrode disposed to be spaced apart from the first pixel electrode on the substrate, a second sacrificial pattern disposed on an edge of the second pixel electrode, a second light emitting layer disposed on the second pixel electrode, a second common electrode disposed on the second light emitting layer and spaced apart from the first common electrode, and a second inorganic layer disposed on an upper surface of the second common electrode, the side surface of the first bank layer, and a lower surface and an upper surface of the second bank layer, where the pixel defining film exposes the second pixel electrode, the first inorganic layer and the second inorganic layer are disposed to be spaced apart from each other, and a portion of the second bank layer is exposed in a space between the first inorganic layer and the second inorganic layer spaced apart from each other.

The display device may further include a first organic pattern disposed on the second bank layer and including the same material as the first light emitting layer, and a first electrode pattern disposed on the first organic pattern and including the same material as the first common electrode, where the first light emitting layer and the first organic pattern are separated from each other, and the first common electrode and the first electrode pattern are separated from each other.

According to an embodiment of the disclosure, a display device includes a first pixel electrode disposed on a substrate, a sacrificial pattern disposed on the first pixel electrode, a pixel defining film disposed on the substrate and including a body portion and a protrusion portion protruding from the body portion, a first light emitting layer disposed on the first pixel electrode, a first common electrode disposed on the first light emitting layer, a first bank layer disposed on the pixel defining film, and a second bank layer disposed on the first bank layer and having a side surface protruding more than a side surface of the first bank layer, where the protrusion portion of the pixel defining layer is disposed on the first pixel electrode, and is spaced apart from an upper surface of the first pixel electrode, and a space between the protrusion portion of the pixel defining film and the first pixel electrode is filled with the sacrificial pattern.

A lower surface of the protrusion portion of the pixel defining film may not be in contact with the first light emitting layer.

An upper surface of the sacrificial pattern may be in contact with the protrusion portion of the pixel defining film, and a lower surface of the sacrificial pattern may be in contact with the first pixel electrode.

According to an embodiment of the disclosure, a method for fabrication of a display device includes forming a plurality of pixel electrodes and sacrificial layers on a substrate, the plurality of pixel electrodes being spaced apart from each other, and the sacrificial layers being disposed on the pixel electrodes; forming a pixel defining material layer on the sacrificial layers, forming a first bank material layer on the pixel defining material layer, and forming a second bank material layer on the first bank material layer; forming a hole exposing a first pixel electrode of the plurality of pixel electrodes by etching the pixel defining material layer, the first bank material layer, and the second bank material layer; etching a portion of the sacrificial layer exposed through the hole and side surfaces of the first bank material layer exposed through the hole such that portions of a lower surface of the second bank material layer are exposed; forming a first light emitting layer on the first pixel electrode and forming a first common electrode on the first light emitting layer; and forming a first inorganic material layer on the first common electrode.

The forming of the plurality of pixel electrodes and the sacrificial layers on the substrate may include forming a metal electrode layer on the substrate and forming a sacrificial material layer on the metal electrode layer, forming a mask pattern on the sacrificial material layer and etching portions of the sacrificial material layer and the metal electrode layer that are not covered by the mask pattern, and heat-treating remaining portions of the sacrificial material layer and the metal electrode layer that are covered by the mask pattern.

The etching of the portion of the sacrificial layer exposed through the hole and the side surfaces of the first bank material layer exposed through the hole may be exposed includes performing a wet etching process that uses an etchant including phosphorus (P), fluorine (F), or nitrogen (N).

In the forming of the first light emitting layer on the first pixel electrode and the forming of the first common electrode on the first light emitting layer, a first organic pattern material layer separated from the first light emitting layer may be formed on the second bank material layer, and a first electrode pattern material layer separated from the first common electrode may be formed on the first organic pattern material layer, and in the forming of the first inorganic material layer on the first common electrode, a monolithic first inorganic material layer may be formed to cover both the first common electrode and the first electrode pattern material layer.

With a display device and a method for fabrication thereof according to an embodiment, the display device includes sacrificial patterns having side surfaces aligned with side surfaces of a pixel defining film or protruding more than the side surfaces of the pixel defining film, and it is thus possible to prevent the occurrence of a mura in the display device and improve reliability of the display device reliability.

In addition, with the display device and the method for fabrication thereof according to an embodiment, by simultaneously performing the formation of undercut structures of a first bank layer and the etching of a sacrificial layer, a process may be simplified.

The effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment;

FIG. 2 is a cross-sectional view of the display device of FIG. 1 viewed from the side;

FIG. 3 is a plan view illustrating an arrangement of light emitting elements, sacrificial patterns, a pixel defining film, trace patterns, and a second bank layer of the display device according to an embodiment;

FIG. 4 is a cross-sectional view illustrating a portion of the display device according to an embodiment;

FIG. 5 is an enlarged view illustrating a first emission area, specifically, area A1, of FIG. 4;

FIG. 6 is an enlarged view illustrating a first emission area according to another embodiment;

FIG. 7 is a cross-sectional view of a case where the sacrificial pattern is depressed compared with the pixel defining film;

FIG. 8 is a flowchart illustrating processes for fabrication of the display device according to an embodiment; and

FIGS. 9 to 16 are cross-sectional views sequentially illustrating the processes for fabrication of the display device according to an embodiment.

### DETAILED DESCRIPTION

The invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Hereinafter, embodiments will be described with reference to the accompanying drawings.

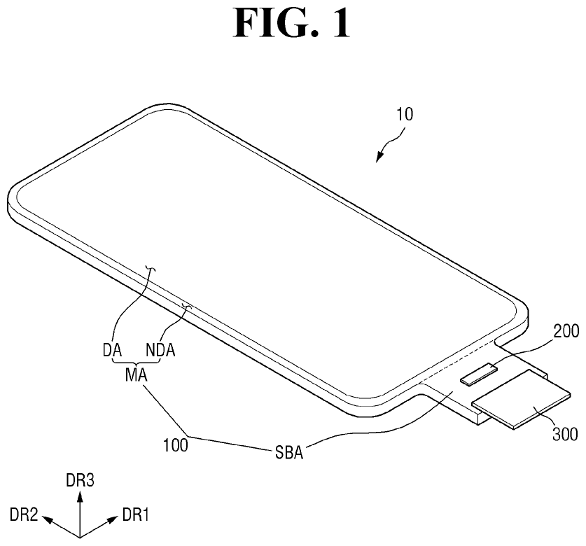

FIG. 1 is a perspective view illustrating a display device according to an embodiment.

Referring to FIG. 1, a display device 10 according to an embodiment may be included in an electronic device to provide a screen displayed on the electronic device. The electronic device may refer to all electronic devices that provide display screens. For example, televisions, laptop computers, monitors, billboards, the Internet of Things (“IoT”), mobile phones, smartphones, tablet personal computers (“PCs”), electronic watches, smart watches, watch phones, head mounted displays, mobile communication terminals, electronic notebooks, electronic books, portable multimedia players (“PMPs”), navigation devices, game machines, digital cameras, camcorders, and the like, which provide display screens, may be included in the electronic device.

A shape of the display device 10 may be variously modified. For example, the display device 10 may have a shape similar to a rectangular shape having short sides in a first direction DR1 and long sides in a second direction DR2. A corner where the short side in the first direction DR1 and the long side in the second direction DR2 meet may be rounded with a curvature, but is not limited thereto, and may also be right-angled in another embodiment. The shape of the display device 10 in a plan view is not limited to the rectangular shape, and may be a shape similar to other polygonal shapes, a circular shape, or an elliptical shape. As used herein, the “plan view” is a view in the third direction DR3.

The display device 10 may include a display panel 100, a display driver 200, a circuit board 300, and a touch driver 400.

The display panel 100 may include a main area MA and a sub-area SBA.

The main area MA may include a display area DA including pixels displaying an image and a non-display area NDA disposed around the display area DA. The display area DA may emit light from a plurality of emission areas or a plurality of opening areas. For example, the display panel 100 may include pixel circuits including switching elements, a pixel defining film defining the emission areas or the opening areas, and self-light emitting elements.

For example, the self-light emitting element may include at least one of an organic light emitting diode (“LED”) including an organic light emitting layer, a quantum dot LED including a quantum dot light emitting layer, an inorganic LED including an inorganic semiconductor, and a micro LED, but is not limited thereto.

A plurality of pixels, a plurality of scan lines, a plurality of data lines, and a plurality of power lines may be disposed in the display area DA. Each of the plurality of pixels may be defined as a minimum unit emitting light, and each of the self-light emitting elements described above may be each of the pixels. The plurality of scan lines may supply scan signals received from a scan driver to the plurality of pixels. The plurality of data lines may supply data voltages received from the display driver 200 to the plurality of pixels. The plurality of power lines may supply source voltages received from the display driver 200 to the plurality of pixels.

The non-display area NDA may be an area outside the display area DA. The non-display area NDA may be defined as an edge area of the main area MA of the display panel 100. The non-display area NDA may include the scan driver supplying the scan signals to the scan lines, and fan-out lines connecting the display driver 200 and the display area DA to each other.

The sub-area SBA may be an area extending from one side of the main area MA. The sub-area SBA may include a flexible material that may be bent, folded, and rolled. For example, when the sub-area SBA is bent, the sub-area SBA may overlap the main area MA in a thickness direction (third direction DR3). The sub-area SBA may include the display driver 200 and pad parts connected to the circuit board 300. In another embodiment, the sub-area SBA may be omitted, and the display driver 200 and the pad parts may be disposed in the non-display area NDA.

The display driver 200 may output signals and voltages for driving the display panel 100. The display driver 200 may supply the data voltages to the data lines. The display driver 200 may supply the source voltages to the power lines and supply scan control signals to the scan driver. The display driver 200 may be formed as an integrated circuit (“IC”) and mounted on the display panel 100 in a chip on glass (“COG”) manner, a chip on plastic (“COP”) manner, or an ultrasonic bonding manner. As an example, the display driver 200 may be disposed in the sub-area SBA, and may overlap the main area MA in the thickness direction (third direction DR3) by bending of the sub-area SBA. As another example, the display driver 200 may be mounted on the circuit board 300.

The circuit board 300 may be attached onto the pad parts of the display panel 100 using an anisotropic conductive film (“ACF”). Lead lines of the circuit board 300 may be electrically connected to the pad parts of the display panel 100. The circuit board 300 may be a flexible printed circuit board, a printed circuit board, or a flexible film such as a chip on film.

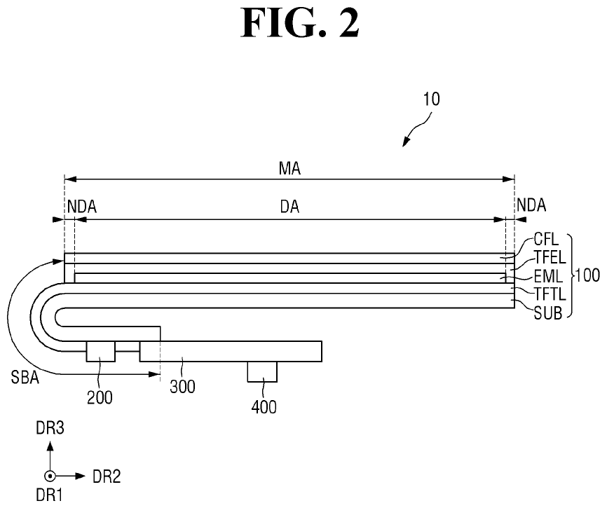

FIG. 2 is a cross-sectional view of the display device of FIG. 1 viewed from the side.

Referring to FIG. 2, the display panel 100 may include a substrate SUB, a thin film transistor layer TFTL, a light emitting element layer EML, a thin film encapsulation layer TFEL, and a color filter layer CFL.

The substrate SUB may be a base substrate or a base member. The substrate SUB may be a flexible substrate that may be bent, folded, and rolled. For example, the substrate SUB may include a polymer resin such as polyimide (“PI”), but is not limited thereto. In another embodiment, the substrate SUB may include a glass material or a metal material.

The thin film transistor layer TFTL may be disposed on the substrate SUB. The thin film transistor layer TFTL may include a plurality of thin film transistors constituting pixel circuits of pixels. The thin film transistor layer TFTL may further include scan lines, data lines, power lines, scan control lines, fan-out lines connecting the display driver 200 and the data lines to each other, and lead lines connecting the display driver 200 and the pad parts to each other. Each of the thin film transistors may include a semiconductor region, a source electrode, a drain electrode, and a gate electrode. For example, when the scan driver is formed on one side of the non-display area NDA of the display panel 100, the scan driver may include thin film transistors.

The thin film transistor layer TFTL may be disposed in the display area DA, the non-display area NDA, and the sub-area SBA. The thin film transistors of each of the pixels, the scan lines, the data lines, and the power lines of the thin film transistor layer TFTL may be disposed in the display area DA. The scan control lines and the fan-out lines of the thin film transistor layer TFTL may be disposed in the non-display area NDA. The lead lines of the thin film transistor layer TFTL may be disposed in the sub-area SBA.

The light emitting element layer EML may be disposed on the thin film transistor layer TFTL. The light emitting element layer EML may include a plurality of light emitting elements each including a first electrode, a second electrode, and a light emitting layer to emit light and a pixel defining film defining the pixels. The plurality of light emitting elements of the light emitting element layer EML may be disposed in the display area DA.

In an embodiment, the light emitting layer may be an organic light emitting layer including an organic material. The light emitting layer may include a hole transporting layer, an organic light emitting layer, and an electron transporting layer. When the first electrode receives a voltage through the thin film transistor of the thin film transistor layer TFTL and the second electrode receives a cathode voltage, holes and electrons may move to the organic light emitting layer through the hole transporting layer and the electron transporting layer, respectively, and may be combined with each other in the organic light emitting layer to emit light.

In another embodiment, the light emitting element may include a quantum dot light emitting diode including a quantum dot light emitting layer, an inorganic light emitting diode including an inorganic semiconductor, or a micro light emitting diode.

The thin film encapsulation layer TFEL may cover an upper surface and side surfaces of the light emitting element layer EML, and may protect the light emitting element layer EML. The thin film encapsulation layer TFEL may include at least one inorganic film and at least one organic film for encapsulating the light emitting element layer EML.

The color filter layer CFL may be disposed on the thin film encapsulation layer TFEL. The color filter layer CFL may include a plurality of color filters each corresponding to the plurality of emission areas. Each of the color filters may selectively transmit light of a specific wavelength therethrough and block or absorb light of other wavelengths. The color filter layer CFL may absorb some of light introduced from the outside of the display device 10 to reduce reflected light by external light. Accordingly, the color filter layer CFL may prevent distortion of colors due to external light reflection.

Since the color filter layer CFL is directly disposed on the thin film encapsulation layer TFEL, the display device 10 may not require a separate substrate for the color filter layer CFL. Accordingly, a thickness of the display device 10 may be relatively small.

In some embodiments, the display device 10 may further include an optical device. The optical device may emit or receive light of infrared, ultraviolet, and visible light bands. For example, the optical device may be an optical sensor sensing light incident on the display device 10, such as a proximity sensor, an illuminance sensor, a camera sensor, a fingerprint sensor, or an image sensor.

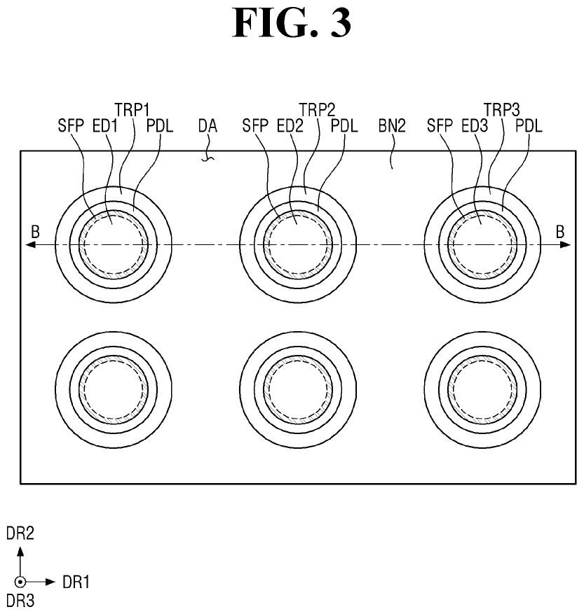

FIG. 3 is a plan view illustrating a portion of the display device according to an embodiment. FIG. 3 is a plan view illustrating an arrangement of light emitting elements ED1, ED2, and ED3, sacrificial patterns SFP, a pixel defining film PDL, trace patterns TRP1, TRP2, and TRP3, and a second bank layer BN2 in the display area DA of the display device 10.

Referring to FIG. 3, the second bank layer BN2 may cover the display area DA, but expose portions of the display area DA. Openings may be formed in exposed areas that are not covered with the second bank layer BN2, and the pixel defining film PDL, the sacrificial patterns SFP, and the light emitting elements ED1, ED2, and ED3 may be disposed within the openings, respectively. The light emitting elements ED1, ED2, and ED may be disposed at the centers of the openings, the sacrificial patterns SFP may be disposed along contours of the light emitting elements ED1, ED2, and ED3, and the pixel defining film PDL may be defined along contours of the sacrificial patterns SFP. In FIG. 3, a case where the sacrificial patterns SFP have side surfaces protruding more than side surfaces of the pixel defining film PDL has been illustrated, and the sacrificial patterns SFP have been illustrated between the light emitting elements ED1, ED2, and ED and the pixel defining film PDL in a plan view. When the side surfaces of the sacrificial patterns SFP are aligned with the side surfaces of the pixel defining film PDL, boundaries of the sacrificial patterns SFP may coincide with boundaries of the pixel defining film PDL in a plan view.

The trace patterns TRP1, TRP2, and TRP3 may be disposed on the second bank layer BN2 along contours of the exposed areas that are not covered with the second bank layer BN2. It has been illustrated in FIG. 3 that the exposed areas that are not covered with the second bank layer BN2 have a circular shape, but the exposed areas may have a polygonal shape such as a triangular shape, a quadrangular shape, or a hexagonal shape, and a shape of the trace patterns TRP1, TRP2, and TRP3 disposed along the contours of the exposed areas may also be changed. The trace patterns TRP1, TRP2, and TRP3 may be disposed at a level above the second bank layer BN2, and the pixel defining film PDL, the sacrificial patterns SFP, and the light emitting elements ED1, ED2, and ED3 may be disposed at a level below the second bank layer BN2.

The exposed areas that are not covered with the second bank layer BN2 may be disposed to be spaced apart from each other in the first direction DR1 and may also be disposed to be spaced apart from each other in the second direction DR2. A shape and an arrangement of the exposed areas that are not covered with the second bank layer BN2 are not limited to those illustrated in FIG. 3, and the exposed areas that are not covered with the second bank layer BN2 may be disposed in a PENTILE™ type.

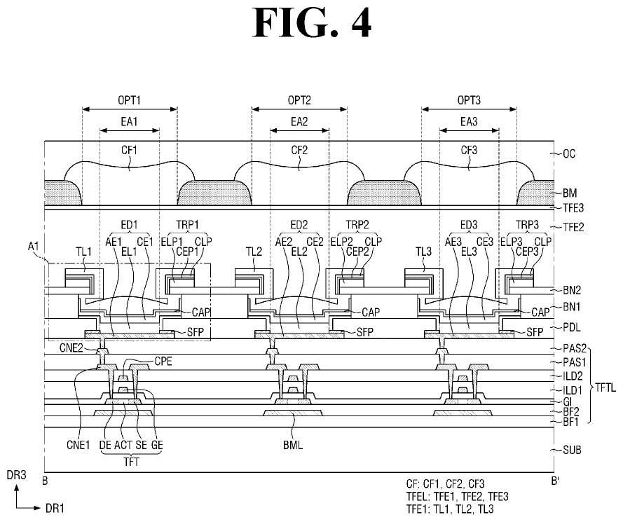

FIG. 4 is a cross-sectional view illustrating a portion of the display device according to an embodiment. Specifically, FIG. 4 is a cross-sectional view taken along line B-B′ of FIG. 3, and illustrates an organic encapsulation film TFE2, a second inorganic encapsulation film TFE3, color filters CF1, CF2, and CF3, a light blocking layer BM, and an overcoat layer OC that are disposed above the plan view of FIG. 3. FIG. 4 illustrates cross sections of the substrate SUB, the thin film transistor layer TFTL, the light emitting element layer EML, the thin film encapsulation layer TFEL, and the color filter layer CFL.

The thin film transistor layer TFTL may include a first buffer layer BF1, a bottom metal layer BML, a second buffer layer BF2, thin film transistors TFT, a gate insulating layer GI, a first interlayer-insulating layer ILD1, capacitor electrodes CPE, a second interlayer-insulating layer ILD2, first connection electrodes CNE1, a first passivation layer PAS1, second connection electrodes CNE2, and a second passivation layer PAS2.

The first buffer layer BF1 may be disposed on the substrate SUB. The first buffer layer BF1 may include an inorganic film capable of preventing permeation of air or moisture. For example, the first buffer layer BF1 may include a plurality of inorganic films that are alternately stacked.

The bottom metal layer BML may be disposed on the first buffer layer BF1. For example, the bottom metal layer BML may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second buffer layer BF2 may cover the first buffer layer BF1 and the bottom metal layer BML. The second buffer layer BF2 may include an inorganic film capable of preventing permeation of air or moisture. For example, the second buffer layer BF2 may include a plurality of inorganic films that are alternately stacked.

The thin film transistor TFT may be disposed on the second buffer layer BF2, and may constitute a pixel circuit of each of the plurality of pixels. For example, the thin film transistor TFT may be a driving transistor or a switching transistor of the pixel circuit. The thin film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the bottom metal layer BML in a plan view and the gate electrode GE in the thickness direction DR3, and may be insulated from the gate electrode GE by the gate insulating layer GI. A material of the semiconductor layer ACT in portions of the semiconductor layer ACT may become conductors to form the source electrode SE and the drain electrode DE.

The gate electrode GE may be disposed on the gate insulating layer GI. The gate electrode GE may overlap the semiconductor layer ACT in the thickness direction DR3 with the gate insulating layer GI interposed therebetween.

The gate insulating layer GI may be disposed on the semiconductor layer ACT. For example, the gate insulating layer GI may cover the semiconductor layer ACT and the second buffer layer BF2, and may insulate the semiconductor layer ACT and the gate electrode GE from each other. The gate insulating layer GI may include contact holes through which the first connection electrodes CNE1 penetrate.

The first interlayer-insulating layer ILD1 may cover the gate electrode GE and the gate insulating layer GI. The first interlayer-insulating layer ILD1 may include contact holes through which the first connection electrodes CNE1 penetrate. The contact holes of the first interlayer-insulating layer ILD1 may be connected to the contact holes of the gate insulating layer GI and contact holes of the second interlayer-insulating layer ILD2.

The capacitor electrodes CPE may be disposed on the first interlayer-insulating layer ILD1. The capacitor electrode CPE may overlap the gate electrode GE in the thickness direction DR3. The capacitor electrode CPE and the gate electrode GE may form capacitance.

The second interlayer-insulating layer ILD2 may cover the capacitor electrodes CPE and the first interlayer-insulating layer ILD1. The second interlayer-insulating layer ILD2 may include contact holes through which the first connection electrodes CNE1 penetrate. The contact holes of the second interlayer-insulating layer ILD2 may be connected to the contact holes of the first interlayer-insulating layer ILD1 and the contact holes of the gate insulating layer GI.

The first connection electrodes CNE1 may be disposed on the second interlayer-insulating layer ILD2. The first connection electrode CNE1 may electrically connect the drain electrode DE of the thin film transistor TFT and the second connection electrode CNE2 to each other. The first connection electrode CNE1 may be inserted into the contact holes formed in the second interlayer-insulating layer ILD2, the first interlayer-insulating layer ILD1, and the gate insulating layer GI to be in contact with the drain electrode DE of the thin film transistor TFT.

The first passivation layer PAS1 may cover the first connection electrode CNE1 and the second interlayer-insulating layer ILD2. The first passivation layer PAS1 may protect the thin film transistor TFT. The first passivation layer PAS1 may include contact holes through which the second connection electrodes CNE2 penetrate.

The second connection electrodes CNE2 may be disposed on the first passivation layer PAS1. The second connection electrodes CNE2 may electrically connect the first connection electrodes CNE1 and pixel electrodes AE1, AE2, and AE3 of the light emitting elements ED to each other. The second connection electrode CNE2 may be inserted into the contact hole formed in the first passivation layer PAS1 to be in contact with the first connection electrode CNE1.

The second passivation layer PAS2 may cover the second connection electrodes CNE2 and the first passivation layer PAS1. The second passivation layer PAS2 may include contact holes through which the pixel electrodes AE1, AE2, and AE3 of the light emitting elements ED penetrate.

The light emitting element layer EML may be disposed on the thin film transistor layer TFTL. The light emitting element layer EML may include light emitting elements ED, a pixel defining film PDL, capping layers CAP, and a bank structure BNS. The light emitting elements ED may include the pixel electrodes AE1, AE2, and AE3, light emitting layers EL1, EL2, and EL3, and common electrodes CE1, CE2, and CE3.

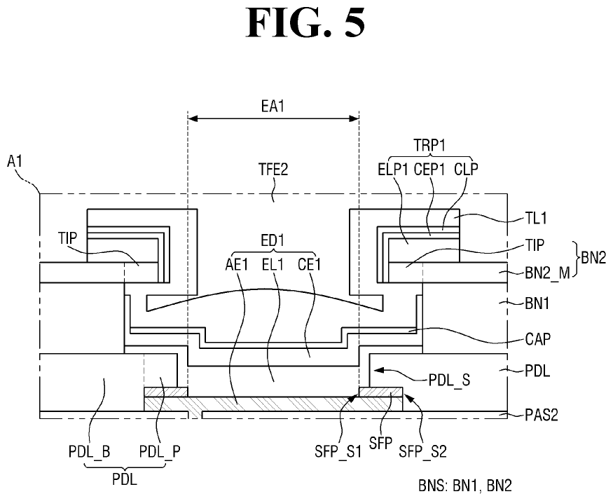

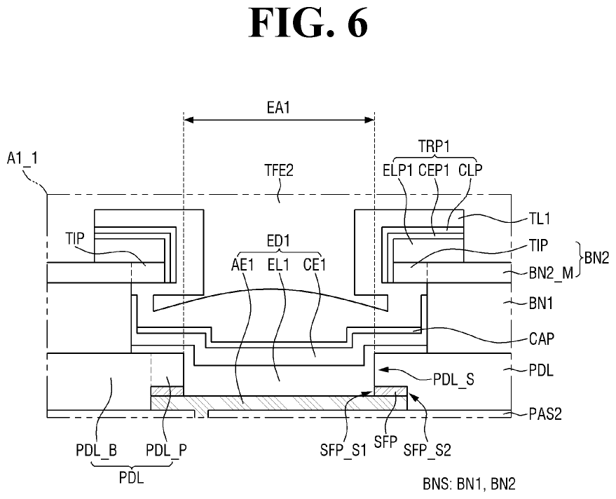

FIG. 5 is an enlarged view illustrating a first emission area, specifically, area A1, of FIG. 4. FIG. 6 is an enlarged view illustrating a first emission area, specifically, area A1_1, according to another embodiment.

Referring to FIGS. 5 and 6 in addition FIG. 4, the display device 10 may include a plurality of emission areas EA1, EA2, and EA3 disposed in the display area DA. The emission areas EA1, EA2, and EA3 may include areas in which light is emitted from the light emitting elements ED1, ED2, and ED3 and passes to the color filter layer CFL in the third direction DR3. The emission areas EA1, EA2, and EA3 may include first emission areas EA1, second emission areas EA2, and third emission areas EA3 that are spaced apart from each other and emit light of different colors.

In an embodiment, areas or sizes of the first to third emission areas EA1, EA2, and EA3 may be the same as each other. For example, in the display device 10, the first emission area EA1, the second emission area EA2, and the third emission area EA3 may have the same area. However, the present disclosure is not limited thereto. In the display device 10, areas or sizes of the first to third emission areas EA1, EA2, and EA3 may be different from each other in another embodiment. For example, an area of the second emission area EA2 may be greater than areas of the first emission area EA1 and the third emission area EA3, and an area of the third emission area EA3 may be greater than an area of the first emission area EA1. Intensities of the light emitted from the emission areas EA1, EA2, and EA3 may change depending on the areas of the emission areas EA1, EA2, and EA3, and a color feeling of a screen displayed on the display device 10 may be controlled by adjusting the areas of the emission area EA1, EA2, and EA3. In an embodiment of FIG. 4, it has been illustrated that the areas of the emission areas EA1, EA2, and EA3 are the same as each other, but the present disclosure is not limited thereto.

In the display device 10, one first emission area EA1, one second emission area EA2, and one third emission area EA3 disposed adjacent to each other may form one pixel group. One pixel group may include the emission areas EA1, EA2, and EA3 emitting light of different colors to express a white gradation. However, the present disclosure is not limited thereto, and a combination of the emission areas EA1, EA2, and EA3 constituting one pixel group may be variously modified depending on an arrangement of the emission areas EA1, EA2, and EA3, colors of the light emitted by the emission areas EA1, EA2, and EA3, and the like.

A plurality of openings formed in the bank structure BNS of the light emitting element layer EML are defined along a boundary of the bank structure BNS. A first bank layer BN1 and a second bank layer BN2 of the bank structure BNS may have a shape in which they surround the emission areas EA1, EA2, and EA3. The openings may include the first to third emission areas EA1, EA2, and EA3.

The display device 10 may include a plurality of light emitting elements ED1, ED2, and ED3 disposed in different emission areas EA1, EA2, and EA3. The light emitting elements ED1, ED2, and ED3 may include a first light emitting element ED1 disposed in the first emission area EA1, a second light emitting element ED2 disposed in the second emission area EA2, and a third light emitting element ED3 disposed in the third emission area EA3.

The light emitting elements ED1, ED2, and ED3 may include pixel electrodes AE1, AE2, and AE3, light emitting layers EL1, EL2, and EL3, and common electrodes CE1, CE2, and CE3, respectively, and the light emitting elements ED1, ED2, and ED3 disposed in the different emission areas EA1, EA2, and EA3 may emit light of different colors depending on materials of the light emitting layers EL1, EL2, and EL3, respectively. For example, the first light emitting element ED1 disposed in the first emission area EA1 may emit first light, which is red light, having a peak wavelength in the range of 610 nm to 650 nm, the second light emitting element ED2 disposed in the second emission area EA2 may emit second light, which is green light, having a peak wavelength in the range of 510 nm to 550 nm, and the third light emitting element ED3 disposed in the third emission area EA3 may emit third light, which is blue light, having a peak wavelength in the range of 440 nm to 480 nm. The first to third emission areas EA1, EA2, and EA3 constituting one pixel may include the light emitting elements ED1, ED2, and ED3 emitting the light of the different colors to express a white gradation. Alternatively, the light emitting layers EL1, EL2, and EL3 may include two or more materials emitting the light of the different colors, such that one light emitting layer may emit mixed light. For example, the light emitting layers EL1, EL2, and EL3 may include both of a red light emitting material and a green light emitting material to emit yellow light or include all of a red light emitting material, a green light emitting material, and a blue light emitting material to emit white light.

The pixel electrodes AE1, AE2, and AE3 may be disposed on the second passivation layer PAS2. The pixel electrodes AE1, AE2, and AE3 may be disposed in the plurality of emission areas EA1, EA2, and EA3, respectively. The pixel electrodes AE1, AE2, and AE3 may include a first pixel electrode AE1 disposed in the first emission area EA1, a second pixel electrode AE2 disposed in the second emission area EA2, and a third pixel electrode AE3 disposed in the third emission area EA3. The first pixel electrode AE1, the second pixel electrode AE2, and the third pixel electrode AE3 may be disposed to be spaced apart from each other on the second passivation layer PAS2, respectively. It has been illustrated in FIG. 4 that the first to third pixel electrodes AE1, AE2, and AE3 are spaced apart from each other in the first direction DR1, but the present disclosure is not limited thereto, and the first to third pixel electrodes AE1, AE2, and AE3 may be spaced apart from each other in any one direction within a plane formed by the first direction DR1 and the second direction DR2 in another embodiment.

The pixel electrodes AE1, AE2, and AE3 may be electrically connected to the drain electrodes DE of the thin film transistors TFT through the first and second connection electrodes CNE1 and CNE2. Edges of the pixel electrodes AE1, AE2, and AE3 spaced apart from each other are covered by the pixel defining film PDL, such that the first to third pixel electrodes AE1, AE2, and AE3 may be insulated from each other.

The pixel electrodes AE1, AE2, and AE3 may include a transparent electrode material and/or a conductive metal material. The conductive metal material may be one or more of silver (Ag), copper (Cu), aluminum (Al), nickel (Ni), lanthanum (La), titanium (Ti), and titanium nitride (TiN). The transparent electrode material may be one or more of indium tin oxide (“ITO”), indium zinc oxide (“IZO”), and indium tin zinc oxide (“ITZO”).

Each of the pixel electrodes AE1, AE2, and AE3 may have a multilayer structure. Each of the pixel electrodes AE1, AE2, and AE3 may include transparent electrode layers and a metal layer or include different metal layers. An upper electrode layer of each of the pixel electrodes AE1, AE2, and AE3 adjacent to each of the light emitting layers EL1, EL2, and EL3 may be crystalline, and may have a selectivity with respect to a sacrificial layer SFL and a sacrificial pattern SFP to be described later in wet etching. In an embodiment, the pixel electrodes AE1, AE2, and AE3 may be multilayer films made of ITO/Ag/ITO, Al/TiN, or Al/Ti, and ITO, TiN, or Ti may be a material of the upper electrode layer adjacent to each of the light emitting layer EL1, EL2, and EL3.

The pixel defining film PDL may be disposed on the second passivation layer PAS2 and the pixel electrodes AE1, AE2, and AE3. The pixel defining film PDL may be entirely disposed on the second passivation layer PAS2, but may expose portions of upper surfaces of the first to third pixel electrodes AE1, AE2, and AE3. For example, the pixel defining film PDL may expose the first pixel electrode AE1 in the first emission area EA1, and a first light emitting layer EL1 may be directly disposed on the first pixel electrode AE1.

The pixel defining film PDL may include a body portion PDL_B and a protrusion portion PDL_P protruding from the body portion PDL_B toward each of the emission areas EA1, EA2, and EA3. The protrusion portion PDL_P may be a portion of a side surface of the body portion PDL_B protruding toward each of the emission areas EA1, EA2, and EA3. The protrusion portion PDL_P of the pixel defining film PDL may be disposed on a sacrificial pattern SFP to be described later, and the body portion PDL_B of the pixel defining film PDL may be in contact with the second passivation layer PAS2.

The pixel defining film PDL may include an inorganic insulating material. The pixel defining film PDL may include at least one of a silicon nitride layer, a silicon oxynitride layer, a silicon oxide layer, a titanium oxide layer, an aluminum oxide layer, a tantalum oxide layer, a hafnium oxide layer, a zinc oxide layer, and an amorphous silicon layer, but is not limited thereto.

The sacrificial patterns SFP may be disposed on edges of the pixel electrodes AE1, AE2, and AE3. Specifically, the protrusion portions PDL_P of the pixel defining film PDL and the pixel electrodes AE1, AE2, and AE3 may be spaced apart from each other, and the sacrificial patterns SFP may be disposed in spaces between the protrusion portions PDL_P of the pixel defining film PDL and the pixel electrodes AE1, AE2, and AE3, respectively. In an embodiment, a lower surface of the protrusion portions PDL_P may directly contact an upper surface of the sacrificial patterns SFP, and may not be in contact with the first light emitting layer EL1. When the pixel electrodes AE1, AE2 AE3 have a circular shape, the sacrificial patterns SFP may have a ring shape.

The sacrificial pattern SFP may have a first side surface SFP_S1 adjacent to each of the emission areas EA1, EA2, and EA3 and a second side surface opposite to the first side surface SFP_S1. The first side surface SFP_S1 of the sacrificial pattern SFP may be aligned with a side surface PDL_S of the protrusion portion PDL_P of the pixel defining film PDL or protrude more than the side surface PDL_S of the protrusion portion PDL_P toward each of the emission areas EA1, EA2, and EA3. FIG. 5 relates to an embodiment in which the first side surface SFP_S1 of the sacrificial pattern SFP protrudes more than the side surface PDL_S of the protrusion portion PDL_P toward each of the emission areas EA1, EA2, and EA3, and FIG. 6 relates to an embodiment in which the first side surface SFP_S1 of the sacrificial pattern SFP is aligned with the side surface PDL_S of the protrusion portion PDL_P.

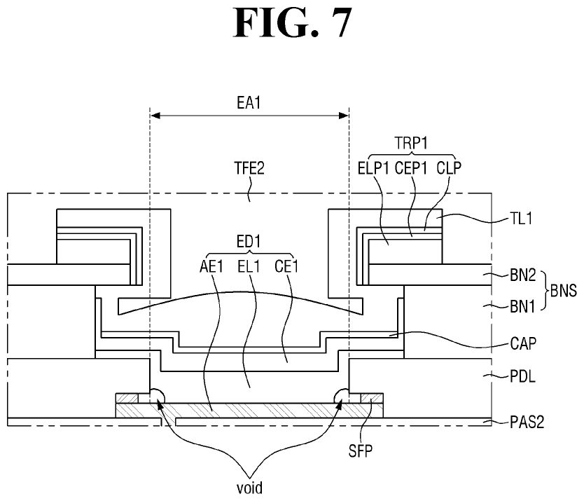

When the sacrificial patterns SFP have side surfaces depressed more than the side surfaces PDL_S of the protrusion portions PDL_P of the pixel defining film PDL to have undercut structures, as illustrated in FIG. 7, the light emitting layers EL1, EL2, and EL3 may not be sufficiently deposited in spaces between the protrusion portions PDL_P of the pixel defining film PDL and the pixel electrodes AE1, AE2, and AE3. In a subsequent process after the deposition, void spaces may be formed at boundaries between the pixel defining film PDL, the sacrificial patterns SFP, and the pixel electrodes AE1, AE2, and AE3. The void spaces may cause a mura or a lighting defect on the display panel. As a driving time increases, the mura on the display panel may become great and reliability of the display panel may deteriorate.

When the sacrificial patterns SFP do not have the undercut structures and have side surfaces aligned with the side surfaces of the protrusion portions PDL_P of the pixel defining film PDL or protruding from the side surfaces of the protrusion portion PDL_P, the light emitting layers EL1, EL2, and EL3 may be smoothly deposited at the boundaries between the pixel defining film PDL, the sacrificial patterns SFP, and the pixel electrodes AE1, AE2, and AE. The void spaces due to the undercut structures may not be generated, and reliability of the display panel may be improved.

Upper surfaces of the sacrificial patterns SFP may be in contact with the protrusion portions PDL_P of the pixel defining film PDL, and lower surfaces of the sacrificial patterns SFP may be in contact with the pixel electrodes AE1, AE2, and AE3.

The protrusion portion PDL_P of the pixel defining film PDL is disposed on the sacrificial pattern SFP, and a width of the protrusion portion PDL_P of the pixel defining film PDL may be a distance from the second side surface of the sacrificial pattern SFP to the side surface PDL_S of the protrusion portion PDL_P of the pixel defining film PDL. A width of the sacrificial pattern SFP may be a distance between the first side surface and the second side surface of the sacrificial pattern SFP. A case where a side surface PDL_S1 of the pixel defining film PDL and the first side surface SFP_S1 of the sacrificial pattern SFP are perpendicular to the substrate SUB has been illustrated in FIGS. 4 to 6, but when these side surfaces are inclined or have a round shape, a length on a boundary surface between the sacrificial pattern SFP and the protrusion portion PDL_P of the pixel defining film PDL may be considered. The width of the sacrificial pattern SFP may be greater than or equal to the width of the protrusion portion PDL_P of the pixel defining film PDL. Accordingly, the entire lower surfaces of the protrusion portions PDL_P of the pixel defining film PDL may be in contact with the sacrificial patterns SFP, and may not be in contact with the light emitting layers EL1, EL2, and EL3. The light emitting layers EL1, EL2, and EL3 may not be disposed between the protrusion portions PDL_P of the pixel defining film PDL and the pixel electrodes AE1, AE2, and AE3.

The sacrificial patterns SFP may include molybdenum (Mo). Molybdenum (Mo) included in the sacrificial patterns SFP may maintain amorphous characteristics even after being heat-treated, and may thus protect the pixel electrodes AE1, AE2, and AE3 disposed beneath the sacrificial patterns SFP in an etching process. In an etching process for forming undercut structures of the first bank layer BN1, molybdenum (Mo) may also be etched, and thus, a separate etching process only for forming the sacrificial patterns SFP may be omitted.

In an embodiment, a thickness of the sacrificial pattern SFP may be 50 angstroms (Å) to 600 Å measured in the third direction DR3. When the thickness of the sacrificial pattern SFP is smaller than 50 Å, it is difficult for sacrificial layers SFL to protect the pixel electrodes AE1, AE2, and AE3 in the etching process. When the thickness of the sacrificial pattern SFP is greater than 600 Å, it may be difficult to form the undercut structures of the first bank layer BN1.

The number of sacrificial patterns SFP may be plural, and the sacrificial patterns SFP may be disposed on the pixel electrodes AE1, AE2, and AE3, respectively. The sacrificial patterns SFP may be spaced apart from each other like the pixel electrodes AE1, AE2, and AE3, respectively, and may be insulated from each other by the pixel defining film PDL. The pixel defining film PDL may be disposed on the second side surface SFP_S2 of the sacrificial pattern SFP. The second side surface SFP_S2 of the sacrificial pattern SFP may be in contact with the body portion PDL_B of the pixel defining film PDL.

The light emitting layers EL1, EL2, and EL3 may be disposed on the pixel electrodes AE1, AE2, and AE3, respectively. The light emitting layers EL1, EL2, and EL3 may be organic light emitting layers made of an organic material, and may be formed on the pixel electrodes AE1, AE2, and AE3, respectively, through a deposition process. When the thin film transistors TFT apply predetermined voltages to the pixel electrodes AE1, AE2, and AE3 of the light emitting elements ED1, ED2, and ED3 and the common electrodes CE1, CE2, and CE3 of the light emitting elements ED1, ED2, and ED3 receives a common voltage or a cathode voltage, holes and electrons may move to the light emitting layers EL1, EL2, and EL3 through hole transporting layers and electron transporting layers, respectively, and may be combined with each other in the light emitting layers EL1, EL2, and EL3 to emit light.

The light emitting layers EL1, EL2, and EL3 may include a first light emitting layer EL1, a second light emitting layer EL2, and a third light emitting layer EL3 each disposed in the different emission areas EA1, EA2, and EA3. The first light emitting layer EL1 may be disposed on the first pixel electrode AE1 in the first emission area EA1, the second light emitting layer EL2 may be disposed on the second pixel electrode AE2 in the second emission area EA2, and the third light emitting layer EL3 may be disposed on the third pixel electrode AE3 in the third emission area EA3. A plurality of light emitting layers EL1, EL2, and EL3 may emit light of different colors, respectively, or one light emitting layer EL1, EL2, or EL3 may emit mixed light. In an embodiment, the first light emitting layer EL1 may emit red light, the second light emitting layer EL2 may emit green light, and the third light emitting layer EL3 may emit blue light. In another embodiment, the first light emitting layer ELL may emit yellow light, which is mixed light of red light and green light, and the second light emitting layer EL2 may emit blue light. In still another embodiment, the first light emitting layer EL1 may emit white light, which is mixed light of red light, green light, and blue light.

The light emitting layers EL1, EL2, and EL3 may be disposed on an upper surface of the pixel defining film PDL. The light emitting layers EL1, EL2, and EL3 may be disposed on the protrusion portions PDL_P of the pixel defining film PDL.

The common electrodes CE1, CE2, and CE3 may be disposed on the light emitting layers EL1, EL2, and EL3, respectively. The common electrodes CE1, CE2, and CE3 may include a transparent conductive material to emit the light generated from the light emitting layers EL1, EL2, and EL3. The common electrodes CE1, CE2, and CE3 may receive a common voltage or a low potential voltage. When the pixel electrodes AE1, AE2, and AE3 receive voltages corresponding to data voltages and the common electrodes CE1, CE2, and CE3 receive the low potential voltage, potential differences are formed between the pixel electrodes AE1, AE2, and AE3 and the common electrodes CE1, CE2, and CE3, such that the light emitting layers EL1, EL2, and EL3 may emit the light.

The common electrodes CE1, CE2, and CE3 may include a first common electrode CE1, a second common electrode CE2, and a third common electrode CE3 each disposed in the different emission areas EA1, EA2, and EA3. The first common electrode CE1 may be disposed on the first light emitting layer EL1 in the first emission area EA1, the second common electrode CE2 may be disposed on the second light emitting layer EL2 in the second emission area EA2, and the third common electrode CE3 may be disposed on the third light emitting layer EL3 in the third emission area EA3. The first to third common electrodes CE1, CE2, and CE3 may be spaced apart from each other.

The capping layers CAP may be disposed on the common electrodes CE1, CE2, and CE3. The capping layers CAP may include an organic or inorganic insulating material and cover patterns disposed on the light emitting elements ED1, ED2, and ED3. The capping layers CAP may prevent the light emitting elements ED1, ED2, and ED3 from being damaged by external air. In an embodiment, the capping layer CAP may include an organic material such as α-NPD, NPB, TPD, m-MTDATA, Alq₃, LiF, and/or CuPc, or an inorganic material such as aluminum oxide, titanium oxide, tantalum oxide, hafnium oxide, zinc oxide, silicon oxide, silicon nitride, and/or silicon oxynitride.

The display device 10 may include a plurality of bank structures BNS disposed on the pixel defining film PDL. The bank structure BNS may have a structure in which bank layers BN1 and BN2 including different materials are sequentially stacked, may include the plurality of openings including the emission areas EA1, EA2, and EA3, and may be disposed so as to overlap a light blocking layer BM in a plan view to be described later. The light emitting elements ED1, ED2, and ED3 of the display device 10 may be disposed to overlap the openings of the bank structure BNS in a plan view.

The bank structure BNS may include a first bank layer BN1 disposed on the pixel defining film PDL and a second bank layer BN2 disposed on the first bank layer BN1.

The first bank layer BN1 may be disposed on the pixel defining film PDL. Side surfaces of the first bank layer BN1 may be depressed more than side surfaces of the pixel defining film PDL in a direction opposite to a direction toward the emission areas EA1, EA2, and EA3. The side surfaces of the first bank layer BN1 may be depressed more than side surfaces of a second bank layer BN2 to be described later in the direction opposite to the direction toward the emission areas EA1, EA2, and EA3.

According to an embodiment, the first bank layer BN1 may include a metal material. The metal material of the first bank layer BN1 may be any material that is removed together with the second bank layer BN2 by dry etching, but is capable of forming an undercut structure by showing an etch rate different from the etch rate of the second bank layer BN2 with respect to wet etching by an alkali-based etchant. In an embodiment, the first bank layer BN1 may include aluminum (Al).

In an embodiment, a thickness of the first bank layer BN1 may be in the range of 4,000 Å to 10,000 Å. When the thickness of the first bank layer BN1 is in the above range, the light emitting layers EL1, EL2, and EL3 and the common electrodes CE1, CE2, and CE3 spaced apart from each other may be formed through deposition and etching processes rather than a mask process.

According to an embodiment, the common electrodes CE1, CE2, and CE3 may be in direct contact with the side surfaces of the first bank layer BN1. The common electrodes CE1, CE2, and CE3 on different light emitting elements ED1, ED2, and ED3 may be in direct contact with corresponding first bank layers BN1, respectively, and the first bank layer BN1 may include the metal material, such that the common electrodes CE1, CE2, and CE3 may be electrically connected to each other through the first bank layer BN1.

The light emitting layers EL1, EL2, and EL3 may be in direct contact with the side surfaces of corresponding first bank layers BN1, respectively. A contact area between the common electrodes CE1, CE2, and CE3 and the side surfaces of the first bank layer BN1 may be greater than a contact area between the light emitting layers EL1, EL2, and EL3 and the side surfaces of the first bank layer BN1. The common electrodes CE1, CE2, and CE3 may be disposed to have a greater area than the light emitting layers EL1, EL2, and EL3 on the side surfaces of the first bank layer BN1 or may be disposed up to a greater height than the light emitting layers EL1, EL2, and EL3 on the side surfaces of the first bank layer BN1. Since the common electrodes CE1, CE2, and CE3 of the different light emitting elements ED1, ED2, and ED3 are electrically connected to each other through the first bank layer BN1, it may be advantageous that the common electrodes CE1, CE2, and CE3 are in contact with the first bank layer BN1 in a greater area.

The second bank layer BN2 may be disposed on the first bank layer BN1. The second bank layer BN2 may include main portions BN2_M of areas disposed on the first bank layer BN1 and tips TIP, which are areas protruding more than the first bank layer BN1. The tip TIP of the second bank layer BN2 may have a shape in which it surrounds the main portion BN2_M. The side surfaces of the second bank layer BN2 may protrude more than the side surfaces of the first bank layer BN1 toward the emission areas EA1, EA2, and EA3.

The side surfaces of the second bank layer BN2 have a shape in which they protrude more than the side surfaces of the first bank layer BN1 toward the emission areas EA1, EA2, and EA3, and accordingly, undercut structures of the first bank layer BN1 may be formed under the tips TIP of the second bank layer BN2. The second bank layer BN2 includes the tips TIP, and thus, the light emitting elements ED1, ED2, and ED3 separated from each other may be formed without a mask process.

Shapes of the side surfaces of the first and second bank layers BN1 and BN2 may be structures formed due to a difference in etch rate in an etching process because the first bank layer BN1 and the second bank layer BN2 include the different materials. According to an embodiment, the second bank layer BN2 may include a material having an etch rate slower than the etch rate of the first bank layer BN1, and the first bank layer BN1 may be further etched in the etching process, such that undercuts may be formed under the tips TIP of the second bank layer BN2. In an embodiment, the first bank layer BN1 may include aluminum (Al), and the second bank layer BN2 may include titanium (Ti).

In processes for fabrication of the display device 10, a mask process is desirable in order to form the light emitting layers EL1, EL2, and EL3 of the light emitting elements ED1, ED2, and ED3 for each of the emission areas EA1, EA2, and EA3. The display device 10 may require a structure for mounting a mask in order to perform the mask process or require an unnecessarily great area of the non-display area NDA in order to control dispersion according to the mask process. When such a mask process is minimized, an unnecessary component such as the structure for mounting the mask may be omitted from the display device 10, and the area of the non-display area NDA for controlling the dispersion may be minimized.

In the display device 10 according to an embodiment, the bank structure BNS includes the tips TIP protruding toward the emission areas EA1, EA2, and EA3, and thus, the light emitting layers EL1, EL2, and EL3 and the common electrodes CE1, CE2, and CE3 may be formed through deposition and etching processes rather than the mask process. In addition, it is possible to form different layers individually in the different emission areas EA1, EA2, and EA3 even through a deposition process. For example, even though the light emitting layers EL1, EL2, and EL3 and the common electrodes CE1, CE2, and CE3 of the light emitting elements ED1, ED2, and ED3 are formed through a deposition process that does not use the mask, deposited materials may be disconnected from each other with the bank structure BNS interposed therebetween by the tips TIP of the second bank layer BN2 rather than being connected to each other between the emission areas EA1, EA2, and EA3. It is possible to form the different layers individually in the different emission areas EA1, EA2, and EA3 through a process of forming a material for forming a specific layer on the entire surface of the display device 10 and then etching and removing a layer formed in unwanted areas. In the display device 10, through the deposition and etching processes without using the mask process, the different light emitting elements ED1, ED2, and ED3 may be formed for each of the emission areas EA1, EA2, and EA3, the unnecessary component may be omitted from the display device 10, and the area of the non-display area NDA may be minimized.

The tips TIP of the second bank layer BN2 may overlap the common electrodes CE1, CE2, and CE3 in a direction DR3 perpendicular to the substrate SUB. In addition, the tips TIP of the second bank layer BN2 may overlap the light emitting layers EL1, EL2, and EL3 in the direction DR3 perpendicular to the substrate SUB. In addition, the tips TIP of the second bank layer BN2 may overlap the pixel defining film PDL in the direction DR3 perpendicular to the substrate SUB. The common electrodes CE1, CE2, and CE3 may be formed under lower surfaces of the tips TIP of the second bank layer BN2. A maximum distance from the substrate SUB to each of the common electrodes CE1, CE2, and CE3 may be smaller than a maximum distance from the substrate SUB to the second bank layer BN2.

According to an embodiment, the side surface PDL_S of the protrusion portion PDL_P of the pixel defining film PDL may protrude more than the side surface of the second bank layer BN2. A width at which the side surface PDL_S of the protrusion portion PDL_P of the pixel defining film PDL protrudes more than the side surface of the first bank layer BN1 may be greater than a width at which the side surface of the second bank layer BN2 protrudes more than the side surface of the first bank layer BN1.

The display device 10 may include the trace patterns TRP1, TRP2, and TRP3 that are traces of the deposition process on the bank structure BNS. The trace patterns TRP1, TRP2, and TRP3 may include organic patterns ELP1, ELP2, and EL3, electrode patterns CEP1, CEP2, and CEP3, and capping patterns CLP, respectively, and may have a shape in which they surround contours of the emission areas EA1, EA2, and EA3 on the second bank layer BN2.

Such trace patterns TRP1, TRP2, and TRP3 may be traces formed while the deposited materials are disconnected from the light emitting layers EL1, EL2, and EL3, the common electrodes CE1, CE2, and CE3, and the capping layers CAP within the emission areas EA1, EA2, and EA3 rather than being connected to the light emitting layers EL1, EL2, and EL3, the common electrodes CE1, CE2, and CE3, and the capping layers CAP within the emission areas EA1, EA2, and EA3 because the bank structure BNS includes the tips TIP. The light emitting layers EL1, EL2, and EL3, the common electrodes CE1, CE2, and CE3, and the capping layers CAP may be formed within the openings, the organic patterns ELP1, ELP2, and ELP3 and the light emitting layers EL1, EL2, and EL3 may be disconnected from each other by the tips TIP of the bank structure BNS, the electrode patterns CEP1, CEP2, and CEP3 and the common electrodes CE1, CE2, and CE3 may be disconnected from each other by the tips TIP of the bank structure BNS, and the capping patterns CLP and the capping layers CAP may be disconnected from each other by the tips TIP of the bank structure BNS. The trace patterns TRP1, TRP2, and TRP3 may be formed by performing patterning around the emission areas EA1, EA2, and EA3 or the openings, respectively.

The display device 10 according to an embodiment may include a plurality of organic patterns ELP1, ELP2, and ELP3 including the same materials as the light emitting layers EL1, EL2, and EL3 and disposed on the bank structure BNS. Since the light emitting layers EL1, EL2, and EL3 are formed through a process of depositing materials on the entire surface of the display device 10, the materials forming the light emitting layers EL1, EL2, and EL3 may be deposited on the bank structure BNS as well as in the emission areas EA1, EA2, and EA2.

For example, the display device 10 may include the organic patterns ELP1, ELP2, and ELP3 disposed above the bank structure BNS. The organic patterns ELP1, ELP2, and ELP3 may include a first organic pattern ELP1, a second organic pattern ELP2, and a third organic pattern ELP3 disposed on the second bank layer BN2 of the bank structure BNS.

The first organic pattern ELP1 may include the same material as the first light emitting layer EL1 of the first light emitting element ED1. The second organic pattern ELP2 may include the same material as the second light emitting layer EL2 of the second light emitting element ED2, and the third organic pattern ELP3 may include the same material as the third light emitting layer EL3 of the third light emitting element ED3. The organic patterns ELP1, ELP2, and ELP3 may be formed in processes of forming the light emitting layers EL1, EL2, and EL3 including the same materials as the organic patterns ELP1, ELP2, and ELP3, respectively. The organic patterns ELP1, ELP2, and ELP3 may be disposed adjacent to the emission areas EA1, EA2, and EA3 in which the light emitting layers EL1, EL2, and EL3, respective, are disposed.

The display device 10 according to an embodiment may include a plurality of electrode patterns CEP1, CEP2, and CEP3 including the same materials as the common electrodes CE1, CE2, and CE3 and disposed on the bank structure BNS. A first electrode pattern CEP1, a second electrode pattern CEP2, and a third electrode pattern CEP3 may be directly disposed on the first organic pattern ELP1, the second organic pattern ELP2, and the third organic pattern ELP3, respectively. An arrangement relationship between the electrode patterns CEP1, CEP2, and CEP3 and the organic patterns ELP1, ELP2, and ELP3 may be the same as an arrangement relationship between the light emitting layers EL1, EL2, and EL3 and the common electrodes CE1, CE2, and CE3 of the light emitting elements ED1, ED2, and ED3.

The display device 10 may include capping patterns CLP disposed above the bank structure BNS. The capping patterns CLP may be directly disposed on the first electrode pattern CEP1, the second electrode pattern CEP2, and the third electrode pattern CEP3 disposed on the second bank layer BN2 of the bank structure BNS. An arrangement relationship between the capping patterns CLP and the electrode patterns CEP1, CEP2, and CEP3 may be the same as an arrangement relationship between the common electrodes CE1, CE2, and CE3 of the light emitting elements ED1, ED2, and ED3 and the capping layers CAP.

The thin film encapsulation layer TFEL may be disposed on the light emitting elements ED1, ED2, and ED3 and the bank structure BNS, and may cover the plurality of light emitting elements ED1, ED2, and ED3 and the bank structure BNS. The thin film encapsulation layer TFEL may include at least one inorganic film to prevent oxygen or moisture from permeating into the light emitting element layer EML. The thin film encapsulation layer TFEL may include at least one organic film to protect the light emitting element layer EML from foreign substances such as dust.

In an embodiment, the thin film encapsulation layer TFEL may include a first inorganic encapsulation film TFE1, an organic encapsulation film TFE2, and a second inorganic encapsulation film TFE3 that are sequentially stacked.

Each of the first inorganic encapsulation film TFEL and the second inorganic encapsulation film TFE3 may include one or more inorganic insulating materials. The inorganic insulating material may be any one of silicon oxide, silicon nitride, and silicon oxynitride, and may be, for example, aluminum oxide, titanium oxide, tantalum oxide, hafnium oxide, zinc oxide, silicon oxide, silicon nitride, and/or silicon oxynitride.

The organic encapsulation film TFE2 may include a polymer-based material. The polymer-based material may include an acrylic resin, an epoxy-based resin, polyimide, polyethylene, and the like. For example, the organic encapsulation film TFE2 may include an acrylic resin such as polymethyl methacrylate or polyacrylic acid. The organic encapsulation film TFE2 may be formed by curing a monomer or applying a polymer.

The first inorganic encapsulation film TFE1 may be disposed on the light emitting elements ED1, ED2, and ED3, the trace patterns TRP1, TRP2, and TRP3, and the bank structure BNS. The first inorganic encapsulation film TFE1 may include a first inorganic layer TL1, a second inorganic layer TL2, and a third inorganic layer TL3 disposed to each correspond to the different emission areas EA1, EA2, and EA3. The first inorganic layer TL1, the second inorganic layer TL2, and the third inorganic layer TL3 may include an inorganic insulating material and cover the light emitting elements ED1, ED2, and ED3, respectively. The first inorganic layer TL1, the second inorganic layer TL2, and the third inorganic layer TL3 may prevent the light emitting elements ED1, ED2, and ED3 from being damaged by external air. The first inorganic layer TL1, the second inorganic layer TL2, and the third inorganic layer TL3 may be disposed to cover the organic patterns ELP1, ELP2, and ELP3, the electrode patterns CEP1, CEP2, and CEP3, and the capping patterns CLP to prevent the patterns disposed on the bank structure BNS from being peeled off during the processes for fabrication of the display device 10.

The first inorganic layer TL1, the second inorganic layer TL2, and the third inorganic layer TL3 may be formed through chemical vapor deposition (“CVD”), and may thus be formed along steps of layers on which they are deposited. For example, the first inorganic layer TL1, the second inorganic layer TL2, and the third inorganic layer TL3 may form thin films even under the undercuts by the tips TIP of the bank structure BNS.

The first inorganic layer TL1 may be disposed on the first light emitting element ED1 and the first electrode pattern CEP1. The first inorganic layer TL1 may be disposed along the first light emitting element ED1, the capping layer CAP, and side surfaces of the second bank layer BN2 adjacent to the first common electrode CE1 so as to cover the first light emitting element ED1, the capping layer CAP, and the side surfaces of the second bank layer BN2 adjacent to the first common electrode CE1, and may also be disposed to cover the first organic pattern ELP1, the first electrode pattern CEP1, and the capping pattern CLP. However, the first inorganic layer TL1 may not overlap a second opening and a third opening in a plan view, and may be disposed only in a first opening and on the bank structure BNS around the first opening. It has been illustrated in FIGS. 4 to 6 that the first inorganic layer TL1 seals a first trace pattern TRP1 and the light emitting element ED1 along outer surfaces of the first trace pattern TRP1 and the light emitting element ED1 at a non-uniform thickness, but the first inorganic layer TL1 may be disposed along an upper surface and side surfaces of the first trace pattern TRP1, side surfaces and a lower surface of the second bank layer BN2, side surfaces of the first bank layer BN1, and an upper surface of the first common electrode CE1 at a uniform thickness.

The second inorganic layer TL2 may be disposed on the second light emitting element ED2 and the second electrode pattern CEP2. However, the second inorganic layer TL2 may not overlap the first opening and the third opening in a plan view, and may be disposed only in the second opening and on the bank structure BNS around the second opening.

The third inorganic layer TL3 may be disposed on the third light emitting element ED3 and the third electrode pattern CEP3. However, the third inorganic layer TL3 may not overlap the first opening and the second opening in a plan view, and may be disposed only in the third opening and on the bank structure BNS around the third opening.

The first inorganic layer TL1 may be formed after the first common electrode CE1 is formed, the second inorganic layer TL2 may be formed after the second common electrode CE2 is formed, and the third inorganic layer TL3 may be formed after the third common electrode CE3 is formed. Accordingly, the first to third inorganic layers TL1, TL2, and TL3 may be disposed to cover different electrode patterns CEP1, CEP2, and CEP3 and organic patterns ELP1, ELP2, and ELP3, respectively. In the plan view of FIG. 3, the first inorganic layer TL1, the second inorganic layer TL2, and the third inorganic layer TL3 may have boundaries that are the same as or similar to those of the first to third trace patterns TRP1, TRP2, and TRP3, respectively, and may have greater areas than the openings of the bank structure BNS or the emission areas EA1, EA2, and EA3, respectively. The first inorganic layer TL1, the second inorganic layer TL2, and the third inorganic layer TL3 may be disposed to be spaced apart from each other on the bank structure BNS. Accordingly, portions of the second bank layer BN2 may not overlap the first to third inorganic layers TL1, TL2, and TL3 in a plan view, and portions of the upper surface of the second bank layer BN2 may be exposed without being covered by the first to third inorganic layers TL1, TL2, and TL3 in spaces between the first to third inorganic layers TL1, TL2, and TL3 spaced apart from each other. The exposed upper surface of the second bank layer BN2 may be in direct contact with the organic encapsulation film TFE2 of the thin film encapsulation layer TFEL.

The light blocking layer BM may be disposed on the thin film encapsulation layer TFEL. The light blocking layer BM may include a plurality of holes OPT1, OPT2, and OPT3 disposed to overlap the emission areas EA1, EA2, and EA3 in a plan view. For example, a first hole OPT1 may be disposed to overlap the first emission area EA1. A second hole OPT2 may be disposed to overlap the second emission area EA2, and a third hole OPT3 may be disposed to overlap the third emission area EA3 in a plan view. An area or a size of each of the holes OPT1, OPT2, and OPT3 may be greater than the area or the size of each of the emission areas EA1, EA2, and EA3. The holes OPT1, OPT2, and OPT3 of the light blocking layer BM are formed to be greater than the emission areas EA1, EA2, and EA3, and accordingly, the light emitted from the emission areas EA1, EA2, and EA3 may be viewed by a user not only from a front surface but also from side surfaces of the display device 10.

The light blocking layer BM may include a light absorbing material. For example, the light blocking layer BM may include an inorganic black pigment or an organic black pigment. The inorganic black pigment may be carbon black, and the organic black pigment may include at least one of lactam black, perylene black, and aniline black, but the present disclosure is not limited thereto. The light blocking layer BM may prevent color mixing due to permeation of visible light between the first to third emission areas EA1, EA2, and EA3 to improve a color gamut of the display device 10.

The display device 10 may include a plurality of color filters CF1, CF2, and CF3 disposed on the emission areas EA1, EA2, and EA3. The plurality of color filters CF1, CF2, and CF3 may be disposed to correspond to the emission areas EA1, EA2, and EA3, respectively. For example, the color filters CF1, CF2, and CF3 may be disposed on the light blocking layer BM including the plurality of holes OPT1, OPT2, and OPT3 disposed to correspond to the emission areas EA1, EA2, and EA3. The holes of the light blocking layer may be formed to overlap the emission areas EA1, EA2, and EA3 or the openings of the bank structures BNS in a plan view, and may form light emitting areas through which the light emitted from the emission areas EA1, EA2, and EA3 is emitted. Each of the color filters CF1, CF2, and CF3 may have a greater area than each of the holes of the light blocking layer BM, and may completely cover the light emitting area formed by each of the holes.

The color filters CF1, CF2, and CF3 may include a first color filter CF1, a second color filter CF2, and a third color filter CF3 disposed to each correspond to the different emission areas EA1, EA2, and EA3. The color filters CF1, CF2, and CF3 may include colorants such as dyes or pigments absorbing light of wavelength bands other than light of a specific wavelength band, and may be disposed to correspond to the colors of the light emitting from the emission areas EA1, EA2, and EA3. For example, the first color filter CF1 may be a red color filter disposed to overlap the first emission area EA1 in a plan view and for transmitting only the first light, which is the red light, therethrough. The second color filter CF2 may be a green color filter disposed to overlap the second emission area EA2 in a plan view and for transmitting only the second light, which is the green light, therethrough, and the third color filter CF3 may be a blue color filter disposed to overlap the third emission area EA3 in a plan view and for transmitting only the third light, which is the blue light, therethrough.

The plurality of color filters CF1, CF2, and CF3 may be spaced apart from other adjacent color filters CF1, CF2, and CF3 on the light blocking layer BM. The color filters CF1, CF2, and CF3 may have greater areas than the holes OPT1, OPT2, and OPT3 of the light blocking layer BM while covering the holes OPT1, OPT2, and OPT3 of the light blocking layer BM, respectively, but may have areas enough to be spaced apart from other color filters CF1, CF2, and CF3 on the light blocking layer BM. However, the present disclosure is not limited thereto. The plurality of color filters CF1, CF2, and CF3 may be disposed to partially overlap other adjacent color filters CF1, CF2, and CF3 in a plan view. Different color filters CF1, CF2, and CF3 may overlap each other on a light blocking layer BM to be described later, which is an area that does not overlap the emission areas EA1, EA2, and EA3. In the display device 10, the color filters CF1, CF2, and CF3 are disposed to overlap each other in a plan view, and accordingly, an intensity of reflected light by external light may be reduced. Furthermore, a color feeling of the reflected light by the external light may be controlled by adjusting an arrangement, shapes, areas, and the like, of the color filters CF1, CF2, and CF3 in a plan view.

The overcoat layer OC may be disposed on the color filters CF1, CF2, and CF3 to planarize upper ends of the color filters CF1, CF2, and CF3. The overcoat layer OC may be a colorless light transmitting layer that does not have a color of a visible light band. For example, the overcoat layer OC may include a colorless light transmitting organic material such as an acrylic resin.

Hereinafter, processes for fabrication of the display device 10 according to an embodiment will be described with reference to other drawings.

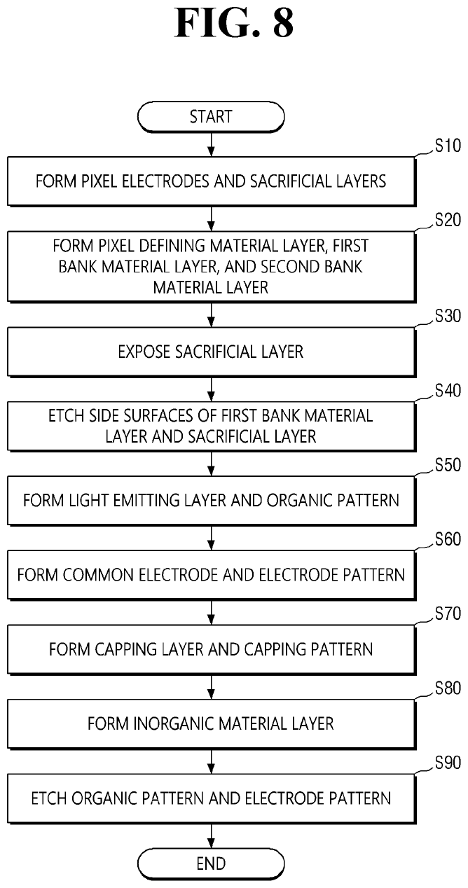

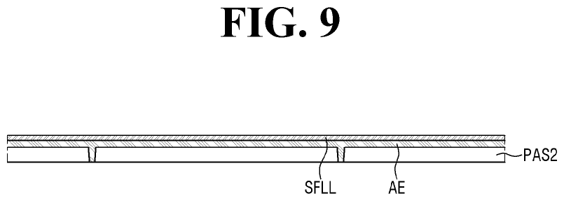

FIG. 8 is a flowchart illustrating processes for fabrication of the display device according to an embodiment, and FIGS. 9 to 16 are detailed cross-sectional views sequentially illustrating the processes for fabrication of the display device according to an embodiment.

In FIGS. 9 to 16, processes of forming the bank structure BNS and the light emitting elements ED as the light emitting element layer EML and the thin film encapsulation layer TFEL of the display device 10 are schematically illustrated. Hereinafter, a description of processes of forming respective layers among the processes for fabrication of the display device 10 will be omitted, and the order of forming the respective layers will be described.

Referring to FIG. 9, a metal electrode layer AE is entirely formed on the second passivation layer PAS2, and a sacrificial material layer SFLL is then formed on the metal electrode layer AE.

Although not illustrated in FIG. 9, the thin film transistor layer TFTL may be disposed on the substrate SUB, and a structure of the thin film transistor TFTL is the same as that described above with reference to FIG. 4. A detailed description thereof will be omitted.

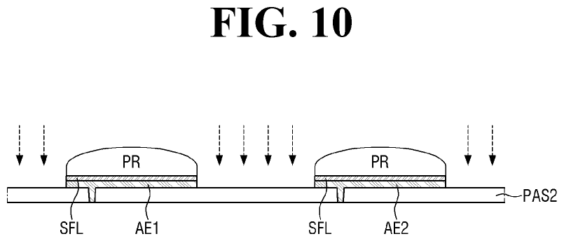

Subsequently, referring to FIG. 10, a mask pattern is formed on the sacrificial material layer SFLL, and a first etching process (1st etching) of removing the sacrificial material layer SFLL and the metal electrode layer AE that are not covered by the mask pattern may be performed. The metal electrode layer may include an amorphous material. A plurality of pixel electrodes AE1 and AE2 spaced apart from each other and sacrificial layers SFL may be obtained by etching the sacrificial material layer SFLL and the metal electrode layer AE together through the first etching process.

When the mask patterns on the plurality of pixel electrodes AE1 and AE2 and the sacrificial layers SFL are removed and heat-treatment is performed, the amorphous materials of the pixel electrodes AE1 and AE2 may be crystallized. When upper electrode layers of the pixel electrodes AE1 and AE2 are crystallized, the upper electrode layers may have a selectivity with respect to the sacrificial layers SFL in a subsequent etching process.

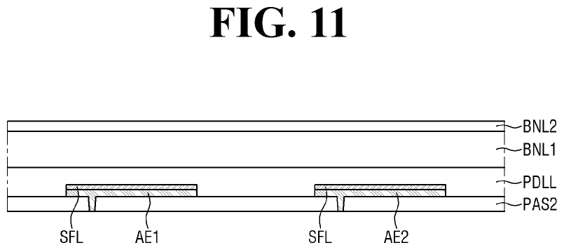

Referring to FIG. 11, a pixel definition material layer PDLL and bank material layers BNL1 and BNL2 may be disposed on the pixel electrodes AE1 and AE2 and the sacrificial layers SFL. The pixel defining material layer PDLL may be disposed to entirely cover the thin film transistor layer TFTL, and first and second bank material layers BNL1 and BNL2 may be disposed to entirely cover the pixel defining material layer PDLL. The bank material layers BNL1 and BNL2 may be partially etched in a subsequent process to form the bank layers BN1 and BN2 of the bank structure BNS illustrated in FIG. 4, respectively.

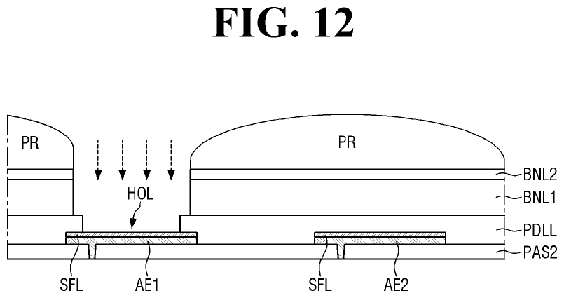

Next, referring to FIG. 12, a photoresist PR is formed on the bank material layers BNL1 and BNL2, and a second etching process (2^{nd} etching) of etching portions of the first and second bank material layers BNL1 and BNL2 and the pixel defining material layer PDLL using the photoresist PR as a mask is performed to form holes HOL1. The holes HOL may be formed in areas overlapping the plurality of pixel electrodes AE1 and AE2, in a plan view and may form the openings of the bank structure BNS.

The photoresists PR may be disposed to be spaced apart from each other on the bank material layers BNL1 and BNL2. The photoresists PR may be disposed on the second bank material layer BNL2 so as to expose a portion overlapping the first pixel electrode AE1 in a plan view.

In an embodiment, dry etching may be performed as the second etching process (2^{nd} etching). The bank material layers BNL1 and BNL2 and the pixel defining material layer PDLL may be anisotropically etched, but due to a difference between materials of the bank material layers BNL1 and BNL2 and the pixel defining material layer PDLL, an etched area of the pixel defining material layer PDLL may be smaller than an etched area of the bank material layers BNL1 and BNL2. In the present process, the sacrificial layers SFL that are amorphous are not etched, and may thus protect the pixel electrodes AE1 and AE2.

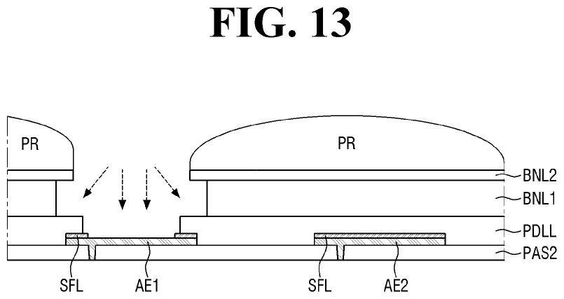

Next, referring to FIG. 13, a portion of the sacrificial layer SFL is etched while undercut structures of the first bank material layer BNL1 are formed through a third etching process (3^{rd} etching).

The first bank material layer BNL1 may have a faster etch rate than the second bank material layer BNL2, and side surfaces of the second bank material layer BNL2 may be formed to protrude more than side surfaces of the first bank material layer BNL1. The side surfaces of the second bank material layer BNL2 protrude more than the side surfaces of the first bank material layer BNL1 toward the hole HOL to form tips TIP, and undercuts may be formed under the tips TIP.

Simultaneously with etching of the side surfaces of the first bank material layer BNL1, the sacrificial layer SFL may be etched A side surface of the sacrificial layer SFL may be aligned with a side surface of the pixel defining material layer PDLL or may protrude more than the side surface of the pixel defining material layer PDLL. In an embodiment, the sacrificial layer SFL includes molybdenum (Mo), and may thus be etched together with the first bank material layer BNL1 without forming undercut structures.

In an embodiment, the third etching process (3rd etching) may be isotropic wet etching. The third etching process may use an etchant including phosphorus (P), fluorine (F), or nitrogen (N).

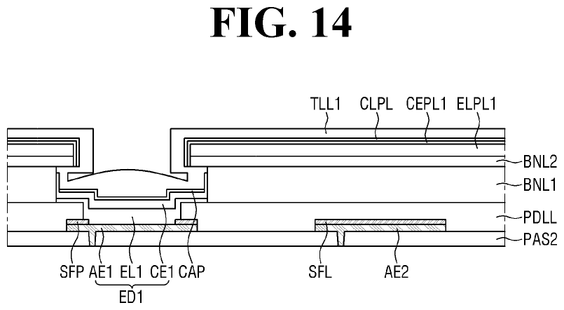

Subsequently, as illustrated in FIG. 14, the photoresist PR formed on the second bank material layer BNK2 is removed, and the first light emitting layer EL1, the first common electrode CE1, and the capping layer CPL are deposited on the first pixel electrode AE1 to form the first light emitting element ED1. In this case, the first light emitting layer EL1, the first common electrode CE1, and the capping layer CAP are formed on the entire surface of the substrate SUB, and thus, a trace pattern may be formed on the second bank material layer BNL2. The trace pattern may include a capping pattern material layer CLPL, a first electrode pattern material layer CEPL1, and a first organic pattern material layer ELPL1. The first organic pattern material layer ELPL1 separated from the first light emitting layer EL1 may be formed on the second bank material layer BNL2, and the first electrode pattern material layer CEPL1 separated from the first common electrode CE1 may be formed on the first organic pattern material layer ELPL1.

The first light emitting layer EL1 and the first common electrode CE1 may be formed through deposition processes. The materials may not be smoothly deposited within the first opening due to the tips TIP of the second bank material layer BNL2. However, the materials of the first light emitting layer EL1 and the first common electrode CE1 are deposited in the direction inclined with the upper surface of the substrate rather than in the direction perpendicular to the upper surface of the substrate, and may thus be deposited even in areas hidden by the tips TIP of the second bank material layer BNL2.

The deposition process of forming the common electrodes CE1, CE2, and CE3 may be performed in an inclined direction relatively closer to a horizontal direction than the deposition process of forming the light emitting layers EL1, EL2, and EL3. Accordingly, the common electrodes CE1, CE2, and CE3 may be in contact with side surfaces of the first bank material layer BNL1 in greater areas than the light emitting layers EL1, EL2, and EL3. Alternatively, the common electrodes CE1, CE2, and CE3 may be deposited up to a higher position on the side surfaces of the first bank material layer BNL1 than the light emitting layers EL1, EL2, and EL3. Different common electrodes CE1, CE2, and CE3 may be in contact with the first bank material layer BNL1 having high conductivity to be electrically connected to each other.

Subsequently, a first inorganic material layer TLL1 covering the first light emitting element ED1 and the capping layer CAP is formed. The first inorganic material layer TLL1 may be formed to completely cover outer surfaces of the first light emitting element ED1, the bank material layers BNL1 and BNL2, the capping layer CAP, and the trace pattern. Specifically, the first inorganic material layer TLL1 is formed on an upper surface of the first common electrode CE1, side surfaces of the first bank material layer BNL1, a lower surface and side surfaces of the second bank material layer BNL2, and an upper surface and side surfaces of the trace pattern.

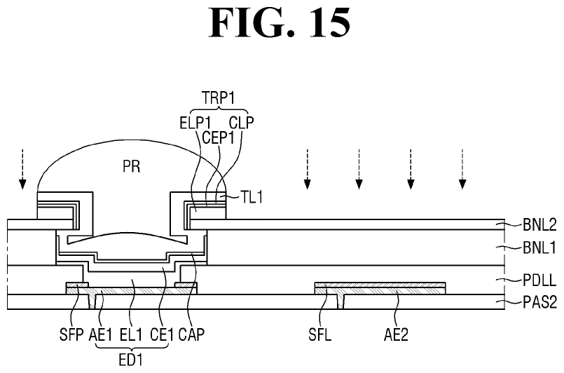

Next, referring to FIG. 15, a photoresist PR of a mask pattern is formed on the first inorganic layer TLL1, and a four etching process (4^{th} etching) of removing the first inorganic layer TLL1 and the trace pattern that are not covered with the mask pattern is performed. In this case, the photoresist PR may be disposed to overlap the first emission area EA1 and an edge area surrounding the first emission area EA1 in a plan view.

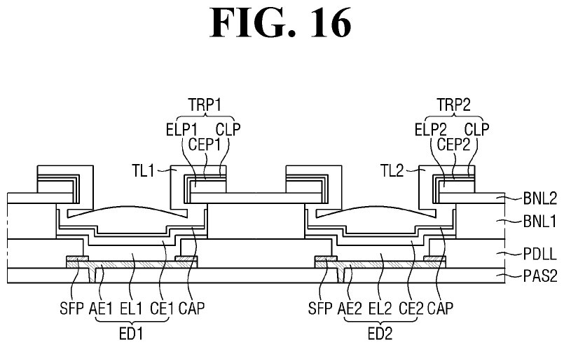

Subsequently, the processes as illustrated in FIGS. 12 to 15 are similarly performed to form the second light emitting layer EL2, the second common electrode CE2, and the capping layer CAP on the second pixel electrode AE2 as illustrated in FIG. 16, the second trace pattern TRP2 surrounding the second light emitting layer EL2, the second common electrode CE2, and the capping layer CAP is formed, and the second inorganic layer TL2 covering the second light emitting element ED2 and the second trace pattern TRP2 is formed.

Subsequently, although not illustrated in the drawings, the display device 10 is fabricated by forming the organic encapsulation film TFE2 and the second inorganic encapsulation film TFE3 of the thin film encapsulation layer TFEL, the light blocking layer BM, the color filter layer CFL, and the overcoat layer OC on the light emitting elements ED1, ED2, and ED3 and the bank structure BNS. Structures of the thin film encapsulation layer TFEL, the light blocking layer BM, the color filter layer CFL, and the overcoat layer OC are the same as those described above, and a detailed description thereof will thus be omitted.

The embodiments of the present disclosure have been described hereinabove with reference to the accompanying drawings, but it will be understood by one of ordinary skill in the art to which the present disclosure pertains that various modifications and alterations may be made without departing from the technical spirit or essential feature of the present disclosure. Therefore, it is to be understood that the embodiments described above are illustrative rather than being restrictive in all aspects.

What is claimed is:

1. A display device comprising:
a first pixel electrode disposed on a substrate;
a first sacrificial pattern disposed on an edge of the first pixel electrode;
a pixel defining film including a body portion disposed on the substrate and a protrusion portion disposed on the first sacrificial pattern and exposing the first pixel electrode;
a first light emitting layer disposed on the first pixel electrode;
a first common electrode disposed on the first light emitting layer;
a first bank layer disposed on the pixel defining film; and
a second bank layer disposed on the first bank layer and having a side surface protruding more than a side surface of the first bank layer,
wherein a first side surface of the first sacrificial pattern is aligned with a side surface of the protrusion portion of the pixel defining film or protrudes more than the side surface of the protrusion portion of the pixel defining film.

2. The display device of claim 1, wherein the first sacrificial pattern includes molybdenum (Mo).

3. The display device of claim 1, wherein the first sacrificial pattern has a second side surface opposite to the first side surface, and
the pixel defining film is disposed on the second side surface of the first sacrificial pattern.

4. The display device of claim 1, wherein the side surface of the protrusion portion of the pixel defining film protrudes more than the side surface of the second bank layer.

5. The display device of claim 1, wherein a thickness of the first sacrificial pattern is 50 angstroms (Å) to 600 Å.

6. The display device of claim 1, wherein an upper surface of the first sacrificial pattern is in contact with the protrusion portion of the pixel defining film, and
a lower surface of the first sacrificial pattern is in contact with the first pixel electrode.

7. The display device of claim 1, wherein the first pixel electrode is a multilayer film made of indium tin oxide (ITO)/silver (Ag)/ITO, aluminum (Al)/titanium nitride (TiN), or Al/Ti.

8. The display device of claim 1, wherein an entire lower surface of the protrusion portion of the pixel defining film is in contact with the first sacrificial pattern.

9. The display device of claim 1, wherein the first common electrode and the first light emitting layer are in contact with the first bank layer, and
a contact area between the first common electrode and the first bank layer is greater than a contact area between the first light emitting layer and the first bank layer.

10. The display device of claim 1, wherein the first bank layer includes aluminum (Al), and
the second bank layer includes titanium (Ti).

11. The display device of claim 1, further comprising a first inorganic layer disposed on an upper surface of the first common electrode, the side surface of the first bank layer, and a lower surface and an upper surface of the second bank layer.

12. The display device of claim 1, further comprising:
a second pixel electrode disposed to be spaced apart from the first pixel electrode on the substrate;
a second sacrificial pattern disposed on an edge of the second pixel electrode;
a second light emitting layer disposed on the second pixel electrode;
a second common electrode disposed on the second light emitting layer and spaced apart from the first common electrode; and
a second inorganic layer disposed on an upper surface of the second common electrode, the side surface of the first bank layer, and a lower surface and an upper surface of the second bank layer,
wherein the pixel defining film exposes the second pixel electrode,
the first inorganic layer and the second inorganic layer are disposed to be spaced apart from each other, and
a portion of the second bank layer is exposed in a space between the first inorganic layer and the second inorganic layer spaced apart from each other.

13. The display device of claim 1, further comprising:
an organic pattern disposed on the second bank layer and including a same material as the first light emitting layer; and
a first electrode pattern disposed on the organic pattern and including a same material as the first common electrode,
wherein the first light emitting layer and the organic pattern are separated from each other, and
the first common electrode and the first electrode pattern are separated from each other.

14. A display device comprising:
a pixel electrode disposed on a substrate;
a sacrificial pattern disposed on the pixel electrode;
a pixel defining film disposed on the substrate and including a body portion and a protrusion portion protruding from the body portion;
a light emitting layer disposed on the pixel electrode;
a common electrode disposed on the light emitting layer;
a first bank layer disposed on the pixel defining film; and
a second bank layer disposed on the first bank layer and having a side surface protruding more than a side surface of the first bank layer,
wherein the protrusion portion of the pixel defining layer is disposed on the pixel electrode, and is spaced apart from an upper surface of the pixel electrode, and
a space between the protrusion portion of the pixel defining film and the pixel electrode is filled with the sacrificial pattern.

15. The display device of claim 14, wherein a lower surface of the protrusion portion of the pixel defining film is not in contact with the light emitting layer.

16. The display device of claim 14, wherein an upper surface of the sacrificial pattern is in contact with the protrusion portion of the pixel defining film, and
a lower surface of the sacrificial pattern is in contact with the pixel electrode.

17. A method for fabrication of a display device, comprising:
forming a plurality of pixel electrodes and sacrificial layers on a substrate, the plurality of pixel electrodes being spaced apart from each other, and the sacrificial layers being disposed on the pixel electrodes;
forming a pixel defining material layer on the sacrificial layers, forming a first bank material layer on the pixel defining material layer, and forming a second bank material layer on the first bank material layer;
forming a hole exposing a pixel electrode of the plurality of pixel electrodes by etching the pixel defining material layer, the first bank material layer, and the second bank material layer;
etching a portion of the sacrificial layer exposed through the hole and side surfaces of the first bank material layer exposed through the hole such that portions of a lower surface of the second bank material layer are exposed;
forming a light emitting layer on the pixel electrode and forming a common electrode on the light emitting layer; and
forming an inorganic material layer on the common electrode.

18. The method for fabrication of the display device of claim 17, wherein the forming of the plurality of pixel electrodes and the sacrificial layers on the substrate includes:
forming a metal electrode layer on the substrate and forming a sacrificial material layer on the metal electrode layer;
forming a mask pattern on the sacrificial material layer and etching portions of the sacrificial material layer and the metal electrode layer that are not covered by the mask pattern; and
heat-treating remaining portions of the sacrificial material layer and the metal electrode layer that are covered by the mask pattern.

19. The method for fabrication of the display device of claim 17, wherein the etching of the portion of the sacrificial layer exposed through the hole and the side surfaces of the first bank material layer exposed through the hole includes performing a wet etching process that uses an etchant including phosphorus (P), fluorine (F), or nitrogen (N).

20. The method for fabrication of the display device of claim 17, wherein in the forming of the light emitting layer on the pixel electrode and the forming of the common electrode on the light emitting layer, an organic pattern material layer separated from the light emitting layer is formed on the second bank material layer, and an electrode pattern material layer separated from the common electrode is formed on the organic pattern material layer, and
in the forming of the inorganic material layer on the common electrode, a monolithic inorganic material layer is formed to cover both the first common electrode and the first electrode pattern material layer.
